(19) United States
(12) Patent Application Publication
(10) Pub. No.: US 2017/0005116 A1
(43) Pub. Date: Jan. 5, 2017

(54) Displays Having Substrate Ledge Support

(71) Applicant: Apple Inc., Cupertino, CA (US)

(72) Inventors: Rohit Ambekar, Sunnyvale, CA (US); Brian D. Strom, Cupertino, CA (US); Tyler R. Kakuda, Stockton, CA (US)

(21) Appl. No.: 14/789,790

(22) Filed: Jul. 1, 2015

(51) Int. Cl. H01L 27/12; G02F 1/1368; G02F 1/1335

(52) U.S. Cl. CPC H01L 27/1248; G02F 1/133528; G02F 1/133514; G02F 1/1368; G02F 2001/133302

(57) ABSTRACT

A display may be provided with display layers and a backlight unit. The display layers may include a thin-film transistor layer having a ledge. The display layers may include an upper polarizer layer and a lower polarizer layer. A color filter layer, liquid crystal layer, and the thin-film transistor layer may be interposed between the upper and lower polarizer layers. A display cover layer may overlap the display layers to serve as a protective layer. Gap filler may be placed between the thin-film transistor ledge and the display cover layer to help prevent the ledge from bending upwards. Support structures may be placed between the thin-film transistor structures and the backlight unit to help prevent the ledge from bending downwards. The support structures may include an extended edge portion of the lower polarizer, a stiffener layer, gap filler, adhesive layers, and other supporting structures.

### BACKGROUND

This relates generally to electronic devices, and, more particularly, to electronic devices with displays.

Electronic devices such as cellular telephones, computers, and other electronic equipment often contain displays for presenting images to a user. Liquid crystal displays and other displays have backlight units that provide backlight for the display. The backlight unit generates light that travels outwards through the pixels of the display. Use of a backlight unit allows a display to display images in a variety of ambient lighting conditions.

Displays such as liquid crystal displays may contain layers of transparent substrate material such as layers of glass. Glass substrate layers may be used in forming display layers such as color filter layers and thin-film transistor layers. The color filter layer in a liquid crystal display may have an array of color filter elements for providing the display with the ability to display color images. The thin-film transistor layer may have thin-film transistor display driver circuitry and an array of pixel circuits that apply signals to pixel electrodes. A layer of liquid crystal material may be interposed between the color filter layer and the thin-film transistor layer. The color filter layer, liquid crystal layer, and thin-film transistor layer may be interposed between upper and lower polarizer layers. During operation of the display, pixel electrodes supply electric fields to corresponding pixel-sized portions of the liquid crystal layer, thereby adjusting the amount of light transmitted through each of the pixels of the display.

The thin-film transistor layer in a liquid crystal display typically extends past the edge of the color filter layer and other layers in the display and thereby forms a thin-film transistor ledge. Because the ledge is less supported than other portions of the display, the ledge may be vulnerable to damage during a drop event. Some support for the thin-film transistor ledge may be provided in the form of adhesive that overlaps the thin-film transistor ledge. A cover glass layer may form the outermost layer of the display to help protect the display. Gap filler adhesive may be interposed between the cover glass layer and portions of the thin-film transistor ledge to help support the thin-film transistor ledge. The use of gap filler adhesive can help reduce damage in the thin-film transistor ledge portion of the display during a drop event, but does not completely eliminate risk of damage.

It would therefore be desirable to be able to provide improved display structures for an electronic device display.

### SUMMARY

A display may be provided with a display layers and a backlight unit. The display layers may include a layer of liquid crystal material sandwiched between a color filter layer and a thin-film transistor layer. The thin-film transistor layer may have a ledge that is not overlapped by the color filter layer. Integrated circuits and a flexible printed circuit cable may be mounted on the thin-film transistor ledge.

The display layers may include an upper polarizer layer and a lower polarizer layer. The color filter layer, liquid crystal layer, and thin-film transistor layers may be interposed between the upper and lower polarizer layers. A display cover layer may overlap the display layers to serve as a protective layer.

Gap filler may be placed between the thin-film transistor ledge and the display cover layer to help prevent the ledge from bending upwards. Support structures may be placed between the thin-film transistor structures and the backlight unit to help prevent the ledge from bending downwards. The support structures may include an extended edge portion of the lower polarizer, a stiffener layer, gap filler, layers of adhesive, and other supporting structures.

### BRIEF DESCRIPTION OF THE DRAWINGS

FIG. 1 is a perspective view of an illustrative electronic device in accordance with an embodiment.

FIG. 2 is a cross-sectional side view of an illustrative electronic device with a display in accordance with an embodiment.

FIG. 3 is a cross-sectional side view of a display with backlight structures that provide illumination for display layers such as liquid crystal display layers in accordance with an embodiment.

FIG. 4 is a cross-sectional side view of an illustrative backlight unit in accordance with an embodiment.

FIG. 5 is a cross-sectional side view of illustrative display layers that may be provided with backlight illumination using a backlight unit of the type shown in FIG. 4 in accordance with an embodiment.

FIG. 6 is a perspective view of an illustrative ledge portion of a thin-film transistor layer in accordance with an embodiment.

FIG. 7 is a cross-sectional side view of an edge portion of a display in accordance with an embodiment.

FIG. 8 is a cross-sectional side view of an edge portion of a display having an extended polarizer layer to help support a thin-film transistor ledge in the display in accordance with an embodiment.

FIG. 9 is a cross-sectional side view of an edge portion of a display having a stiffener to help support the thin-film transistor ledge in the display in accordance with an embodiment.

FIG. 10 is a cross-sectional side view of an edge portion of a display having gap filler adhesive on opposing sides of a thin-film transistor ledge in the display to help support the ledge in accordance with an embodiment.

### DETAILED DESCRIPTION

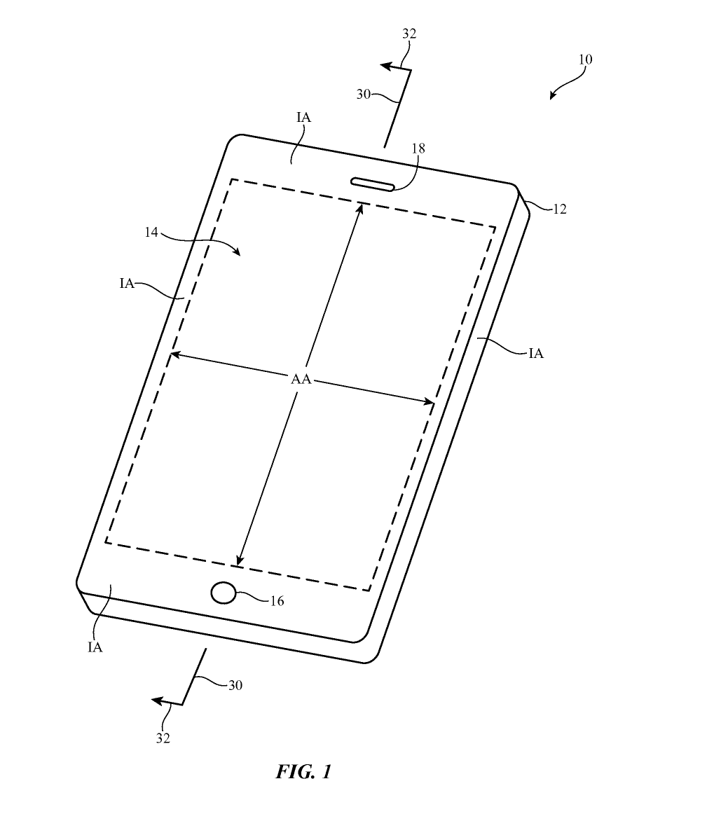

An electronic device such as electronic device 10 of FIG. 1 may contain a display. The display may have a substrate with a ledge portion. The ledge portion may be supported using support structures to help prevent damage to the ledge during a drop event.

Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment. In the illustrative configuration of FIG. 1, device 10 is a portable device such as a cellular telephone, media player, tablet computer, or other portable computing device. Other configurations may be used for device 10 if desired. The example of FIG. 1 is merely illustrative.

In the example of FIG. 1, device 10 includes a display such as display 14 mounted in housing 12. Housing 12, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 12 may be formed using a unibody configuration in which some or all of housing 12 is machined or molded as a single structure or may be formed using multiple structures (e.g., an internal frame structure, one or more structures that form exterior housing surfaces, etc.).

Display 14 may be a touch screen display that incorporates a layer of conductive capacitive touch sensor electrodes or other touch sensor components (e.g., resistive touch sensor components, acoustic touch sensor components, force-based touch sensor components, light-based touch sensor components, etc.) or may be a display that is not touch-sensitive. Capacitive touch screen electrodes may be formed from an array of indium tin oxide pads or other transparent conductive structures.

Display 14 may be protected using a display cover layer such as a layer of transparent glass, clear plastic, sapphire, or other transparent material. Openings may be formed in the display cover layer. For example, an opening may be formed in the display cover layer to accommodate a button such as button 16. An opening may also be formed in the display cover layer to accommodate ports such as speaker port 18. Openings may be formed in housing 12 to form communications ports (e.g., an audio jack port, a digital data port, etc.), to form openings for buttons, etc.

Display 14 may include an array of pixels formed from liquid crystal display (LCD) components, an array of electrophoretic pixels, an array of plasma pixels, an array of organic light-emitting diode pixels or other light-emitting diodes, an array of electrowetting pixels, or pixels based on other display technologies. Illustrative configurations for display 14 that are based on liquid crystal display structures are sometimes described herein as an example. This is, however, merely illustrative. Display 14 may use any suitable type of display technology.

The array of pixel in display 14 forms an active area AA. Active area AA is used to display images for a user of device 10. Active area AA may be rectangular or may have other suitable shapes. Inactive border area IA may run along one or more edges of active area AA. Inactive border area IA may contain circuits, signal lines, and other structures that do not emit light for forming images and does not contain any pixels. In some configurations for display 14, the widths of at least some of borders IA may be minimized or eliminated (e.g., to form a borderless display). For example, the borders of device 10 of FIG. 1 may be minimized or eliminated along the right and left edge of device 10.

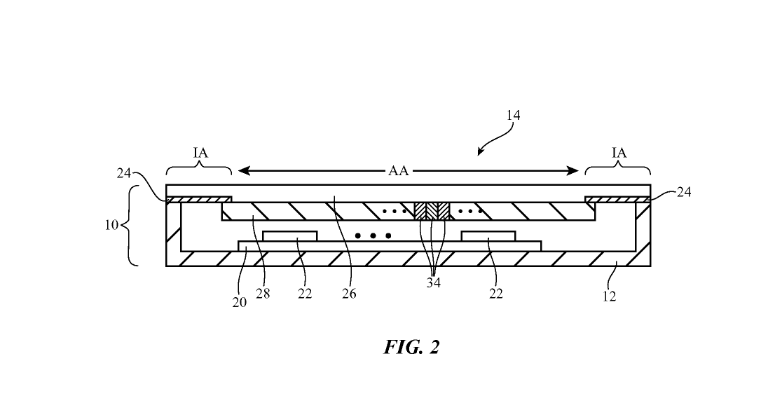

FIG. 2 is a cross-sectional side view of device 10 of FIG. 1 taken along line 30 and viewed in direction 32. As shown in FIG. 2, device 10 may include electrical components 22. Electrical components 22 may include integrated circuits, sensors, connectors, batteries, audio circuits, speakers, microphones, and other input-output devices and control circuitry. Electrical components 22 may be mounted on one or more substrates such as substrate 20. Substrates such as substrate 20 may be formed from plastic, glass, ceramic, other dielectric materials, printed circuits (e.g., rigid printed circuits formed from fiberglass-filled epoxy or other rigid printed circuit material and/or flexible printed circuits formed from flexible layers of polyimide or sheets of other polymer substrate materials), or other substrate material.

Display 14 may have an outermost layer such as display cover layer 26. Layer 26 may be formed from a transparent material that helps protect display 14 such as a layer of transparent plastic, clear glass, sapphire, or other protective display layer. Display module 28 (sometimes referred to as display structures) may contain pixels such as pixels 34. Pixels 34 may be arranged in a rectangular array of rows and columns or other suitable layouts to display images for a user of device 10. Pixels 34 produce images in active area AA of display 14. Inactive areas IA of display 14 do not contain pixels 34 and do not produce images. To block potentially unsightly interior components from view in device 10, the underside of the edges of display cover layer 26 may be coated with a layer of opaque masking material 24. Opaque masking material 24 may have the shape of a rectangular ring that surrounds a central rectangular active area AA or may have other suitable shapes. Opaque masking material 24 may be formed from a layer of black or white ink, metal, opaque plastic, or other opaque materials.

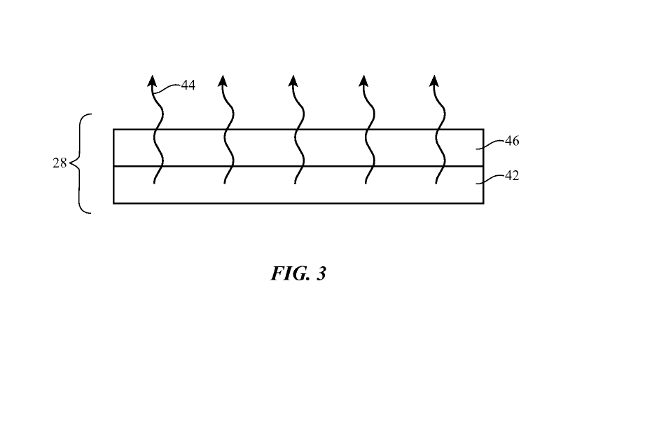

Display module 28 may have a backlight unit (sometimes referred to as backlight structures) for supplying display 14 with backlight illumination. A cross-sectional side view of an illustrative display module with a backlight unit is shown in FIG. 3. As shown in FIG. 3, display module 28 may include display layers 46 and backlight unit 42. Display layers 46 may include an array of pixels 34 with controllable transparencies for displaying images for a user of device 10. Backlight unit 42 may provide backlight illumination 44 that travels outward through display layers 46, thereby illuminating the array of pixels in display layers 46 and helping a user of device 10 view images on display 14. Backlight unit 42 may be based on light-emitting devices such as light-emitting diodes. Display layers 46 may be liquid crystal display layers.

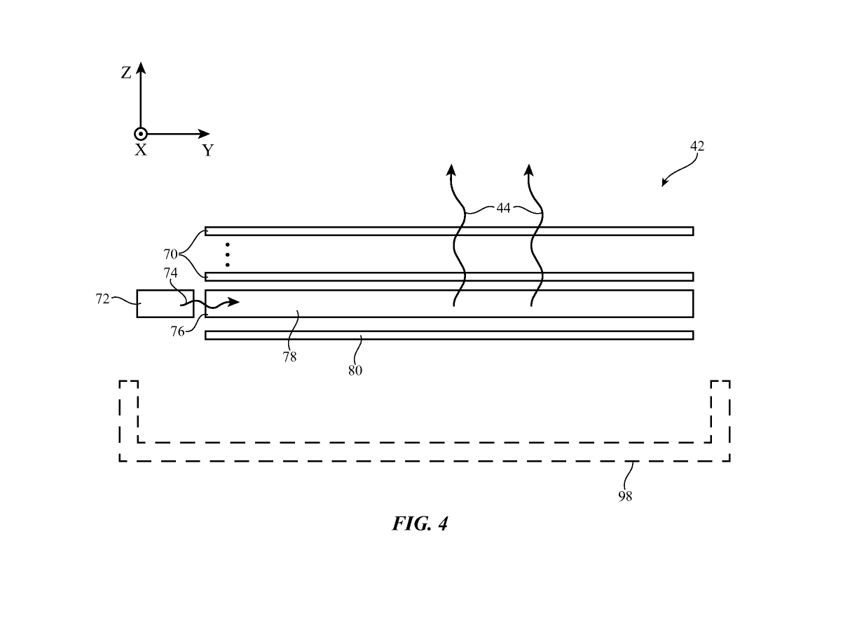

An illustrative backlight unit is shown in FIG. 4. As shown in FIG. 4, backlight unit 42 may produce backlight illumination (backlight) 44. During operating, backlight 44 travels outwards (vertically upwards in dimension Z in the orientation of FIG. 4) and passes through pixels 34 in display layers 46 (FIG. 3). This illuminates images that are being produced by the pixels for viewing by a user. The structures that form backlight unit 42 may be supported using optional support structures 98 (e.g., a chassis, a portion of housing 12, etc.).

Backlight unit 42 may include a light guide layer such as light guide layer 78. Light guide layer 78 may be formed from a transparent material such as clear glass or plastic (e.g., a molded clear plastic light guide plate or a thin flexible plastic light guide film). During operation of backlight unit 42, a light source such as light source 72 may generate light 74. Light source 72 may be, for example, an array of light-emitting diodes. If desired, light sources such as light source 72 may be located along multiple edges of light guide layer 78.

Light 74 from light source 72 may be coupled into edge surface 76 of light guide layer 78 and may be distributed in dimensions X and Y throughout light guide layer 78 due to the principal of total internal reflection. Light guide layer 78 may include light-scattering features such as pits or bumps. The light-scattering features may be located on an upper surface and/or on an opposing lower surface of light guide layer 78.

Light 74 that scatters upwards in direction Z from light guide layer 78 may serve as backlight 44 for display 14. Light 74 that scatters downwards may be reflected back in the upward direction by a reflective film such as reflector 80. Reflector 80 may be formed from a reflective material such as a reflective layer of white plastic or other reflective materials.

To enhance backlight performance for backlight structures 42, backlight structures 42 may include optical films 70. Optical films 70 may include one or more diffuser layers for helping to homogenize backlight 44 and thereby reduce hotspots and one or more prism films (also sometimes referred to as turning films or brightness enhancement films) for collimating backlight 44. Compensation films for enhancing off-axis viewing may be included in optical films 70 or may be incorporated into other portions of display 14 (e.g., in polarizer layers such as layers 54 and/or 60). If desired, optical films 70 may include other layers of material (e.g., wave plates) and/or one or more of the layers of backlight unit 42 of FIG. 4 may be omitted. Optical films 70 may overlap other structures in backlight unit 42 such as light guide layer 78 and reflector 80. For example, if light guide layer 78 has a rectangular footprint in the X-Y plane of FIG. 4, optical films 70 and reflector 80 may have a matching rectangular footprint.

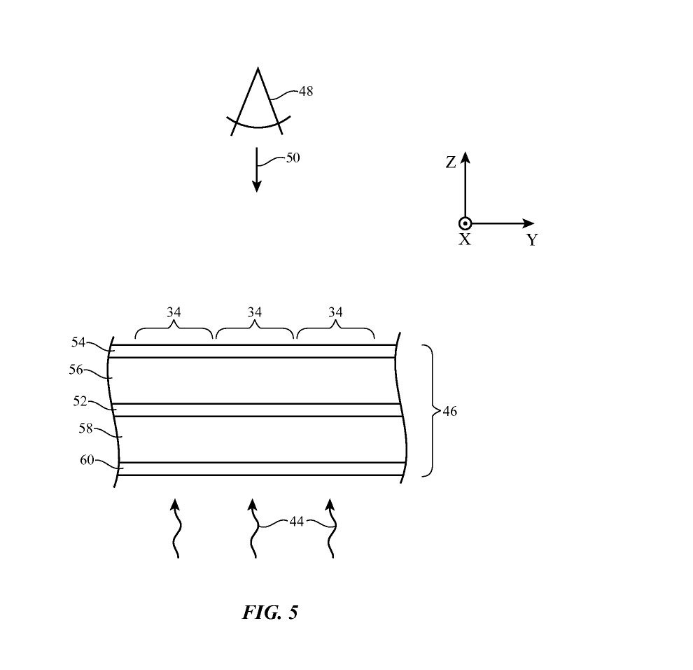

Illustrative display layers 46 for display module 28 are shown in FIG. 5. Display layers 46 may be illuminated by backlight illumination 44 from backlight unit 42 of FIG. 4. In a configuration in which display layers 46 are used in forming a liquid crystal display, display layers 46 may include a liquid crystal layer such a liquid crystal layer 52. Liquid crystal layer 52 may be sandwiched between display layers such as display layers 58 and 56. Layers 56 and 58 may be interposed between lower polarizer layer 60 and upper polarizer layer 54.

Layers 58 and 56 may be formed from transparent substrate layers such as clear layers of glass or plastic. Layers 56 and 58 may be layers such as a thin-film transistor layer and/or a color filter layer. Conductive traces, color filter elements, transistors, and other circuits and structures may be formed on the substrates of layers 58 and 56 (e.g., to form a thin-film transistor layer and/or a color filter layer). Touch sensor electrodes may also be incorporated into layers such as layers 58 and 56 and/or touch sensor electrodes may be formed on other substrates.

With one illustrative configuration, layer 58 may be a thin-film transistor layer that includes an array of thin-film transistors and associated electrodes (display pixel electrodes) for applying electric fields to pixel-sized portions of liquid crystal layer 52 and thereby displaying images on display 14. Layer 56 may be a color filter layer that includes an array of color filter elements for providing display 14 with the ability to display color images. If desired, lower layer 58 may be a color filter layer and upper layer 56 may be a thin-film transistor layer. Another illustrative configuration for display layers 46 involves forming color filter elements and thin-film transistor circuits with associated pixel electrodes on a common substrate. This common substrate may be the upper substrate or may be the lower substrate and may be used in conjunction with an opposing glass or plastic layer (e.g., a layer with or without any color filter elements, thin-film transistors, etc.) to contain liquid crystal layer 52. For example, thin-film transistor layer 58 may include color filter elements and may be located above or below liquid crystal layer 52). Illustrative configurations for display 14 in which layer 58 is a thin-film transistor layer and layer 56 is a color filter layer are sometimes described herein as an example.

During operation of display 14 in device 10, control circuitry (e.g., one or more integrated circuits on a printed circuit) may be used to generate information to be displayed on an array of pixels 34 of display 14 (e.g., display data). The information to be displayed may be conveyed to one or more display driver integrated circuits and other display driver circuitry (e.g., thin-film gate drivers, etc.) using a signal path such as a signal path formed from conductive metal traces in a rigid or flexible printed circuit. Backlight illumination 44 that is traveling outwards (vertically upwards in dimension Z in the orientation of FIG. 5) passes through pixels 34 in display layers 46. This illuminates any images that are being produced by pixels 34 for viewing by a user. For example, backlight 44 may illuminate images on display layers 46 that are being viewed by user 48 in direction 50.

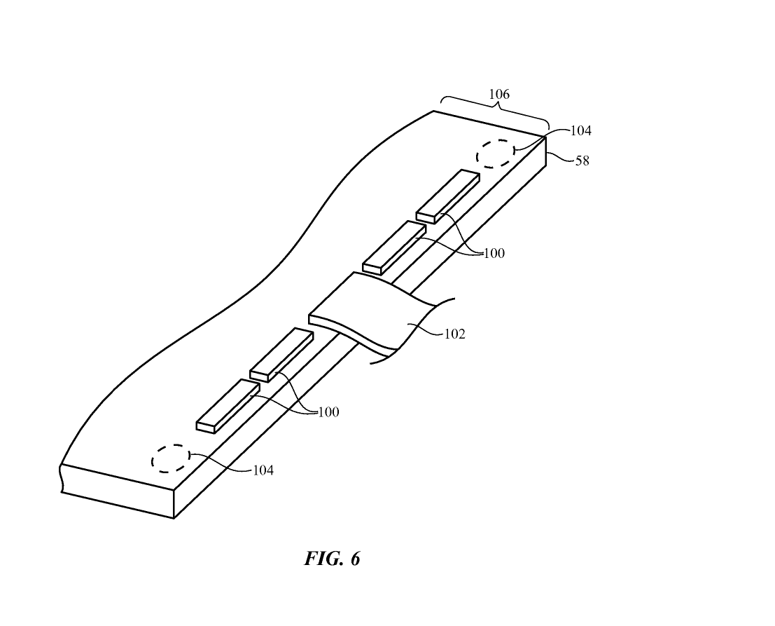

It may be desirable to provide thin-film transistor layer 58 with a portion that extends outward from under color filter layer 56 such as a region forming a thin-film transistor ledge. This ledge may contain contact pads coupled to thin-film transistor display driver circuitry and pixel circuits in the array of pixels 34. Display driver integrated circuits and/or flexible printed circuit cables may be coupled to the contact pads using solder and/or conductive adhesive (e.g., anisotropic conductive film). A perspective view of an illustrative region of thin-film transistor layer 58 that forms a ledge is shown in FIG. 6. In the illustrative configuration of FIG. 6, display driver integrated circuits such as integrated circuits 100 have been soldered to contact pads on thin-film transistor ledge 106 and a flexible printed circuit cable has been coupled to contact pads on thin-film transistor ledge 106 using conductive adhesive.

Thin-film transistor ledge 106 contains components such as integrated circuits 100 and flexible printed circuit 102 and therefore does not contain any pixels 34 and does not display images (i.e., ledge 106 overlaps inactive area IA). Because ledge 106 extends outward from other layers 46 such as color filter layer 56, ledge 106 is less supported than other portions of thin-film transistor layer 58 and therefore may have an elevated risk of becoming damaged during a drop event. Ledge 106 forms a diving board structure that is prone to bending when device 10 is dropped and strikes a hard surface. Bending of this type may cause metal traces and other structures on thin-film transistor layer ledge 106 to crack, may cause solder joints for integrated circuits 100 to fail, may damage the anisotropic conductive film bonds formed between printed circuit 102 and the thin-film transistor layer contacts on ledge 106, and/or may otherwise damage thin-film transistor layer 58.

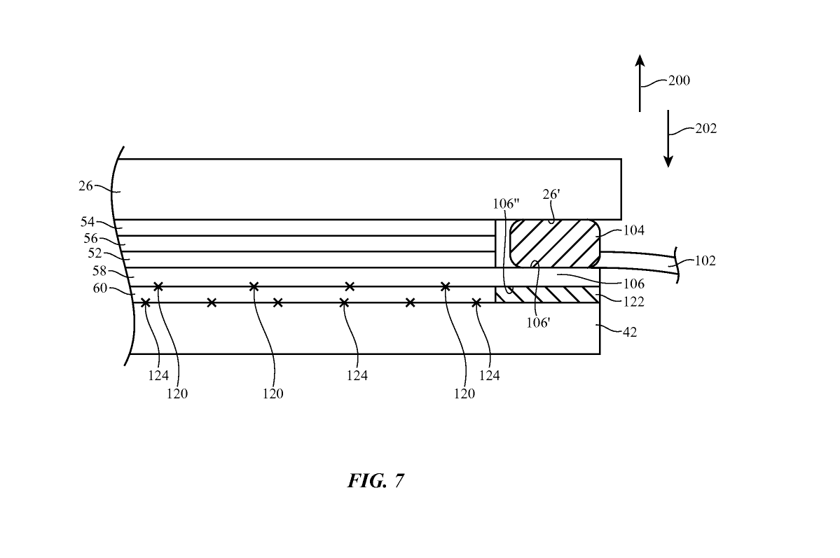

To help support ledge 106, gap filler 104 (e.g., drops of ultraviolet-light-cured or thermally cured epoxy or other adhesive) may be formed in corner regions of the upper surface of ledge 106. Gap filler 104 may couple thin-film transistor ledge 106 to the underside of display cover layer 26. Further support for ledge 106 may be provided on the opposing side of thin-film transistor layer 58 (e.g. on the lower side of ledge 106), as shown by illustrative support structures 122 of FIG. 7. As shown in FIG. 7, gap filler 104 may extend between lower surface 26′ of display cover layer 26 and upper surface 106′ of thin-film transistor ledge 106. This helps prevent ledge 106 from bending in upwards direction 200. Support structures 122 may be formed between lower surface 106″ of ledge 106 and the upper surface of one or more structures in backlight unit 42 (e.g., optical film layers, light guide layers, light-emitting diodes, chassis structures or other support structures formed within backlight unit 42, etc.). The presence of support structures 122 may help prevent ledge 106 from bending in downwards direction 202.

Support structures 122 may be formed from one or more layers of material such as plastic, ceramic, glass, metal, or other suitable structures. As shown in FIG. 7, display layers such as lower polarizer 60 may be attached to the lower surface of thin-film transistor layer 58 using adhesive layer 120 (e.g., optically clear adhesive, etc.). Adhesive 124 may be used in attaching the lower polarizer 60 to backlight unit 42. Adhesive 124 may be a rectangular ring of pressure sensitive adhesive that runs along the edge of display 14 in inactive area IA or may be optically clear adhesive or other suitable adhesive. If desired, layers formed from adhesive 120 (e.g., a layer of liquid optically clear adhesive) and/or adhesive 124 (e.g., a pressure sensitive adhesive layer) may be included in support structures 122 (e.g., support structures 122 may include an upper adhesive layer formed from a portion of layer 120 and a lower adhesive layer formed from a portion of layer 124).

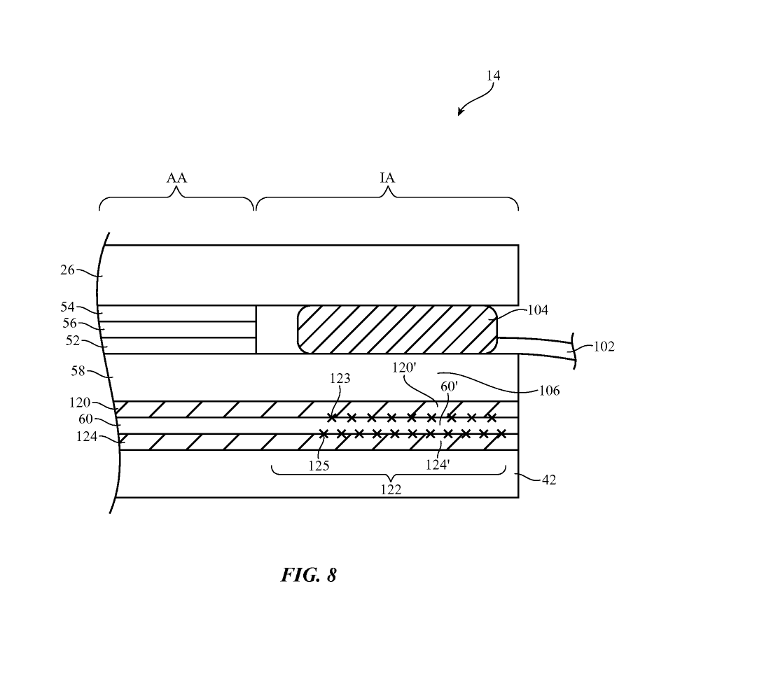

In the illustrative configuration of FIG. 8, support structures 122 have been formed from extended portion 60′ of lower polarizer layer 60 and extended portions 120′ and 124′ of respective adhesive layers 120 and 124. If desired, other portions of display layers 46 may be used in forming support structures 122. The use of a portion of polarizer layer 60 to form support layer 122 is illustrative. Polarizer layer 60 may be formed from layers of polymer (e.g., layers of triacetyl cellulose and polyvinyl alcohol, etc.). These layers may be deform slightly when ledge 106 deflects and may thereby help to dampen vibrations induced in ledge 106 in the event that device 10 is dropped. If desired, one or more additional layers of material may be incorporated into support structures 122 above or below extended edge region 60′ of polarizer layer 60, as illustrated by layers 123 and 125. Layers 123 and/or 125 may include, for example, layers of polymer, metal, glass, ceramic, or other materials.

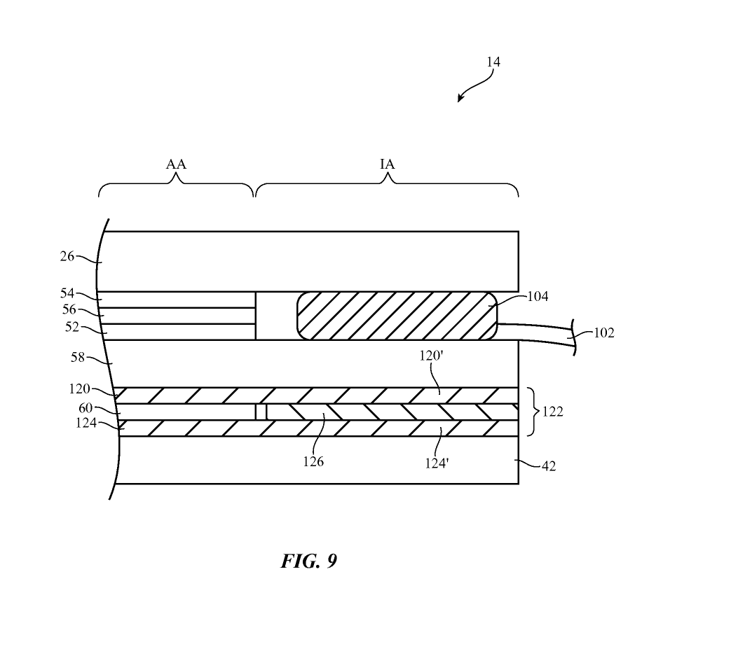

FIG. 9 is a cross-sectional side view of display 14 in an illustrative configuration in which support structures 122 have been formed from a stiffener layer such as layer 126. Support structures 122 may also include portions 120′ and 124′ of adhesive layers 120 and 124, respectively. Stiffener layer 126 may be formed from one or more layers of material such a plastic (e.g., a rigid plastic layer or flexible plastic layer), metal (e.g., a thin strip of stainless steel), fiberglass, carbon-fiber composite, or other fiber composites, ceramic, glass, or other materials. Stiffener layer 126 may be formed from the same material as adhesive 120 and/or adhesive 124 or layers 120, 124, and 126 may be formed from different materials.

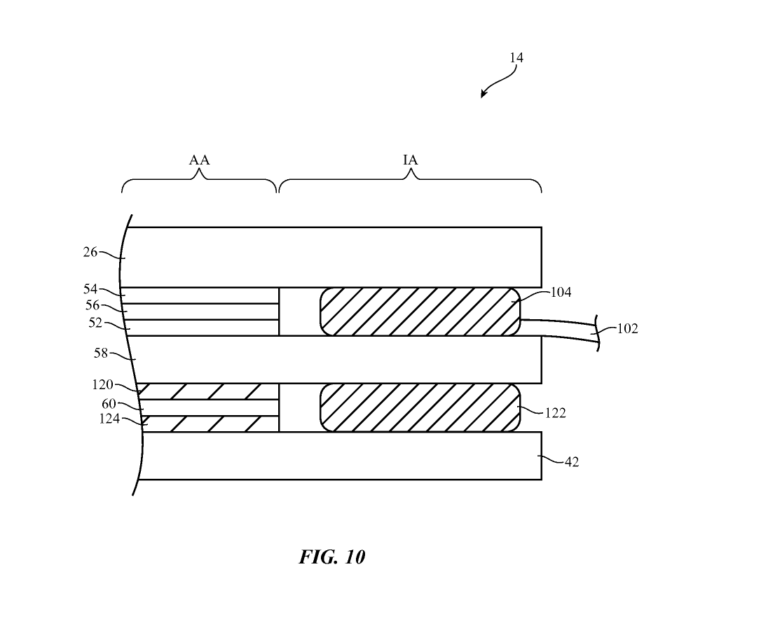

FIG. 10 shows how support structures 122 may be formed from a gap filler such as an epoxy gap filler layer (e.g., a layer of material formed from the same substance as gap filler 104). Gap filler layer 122 may be cured using ultraviolet light, heat, or other curing techniques and may extend across the width of display 14 or may be deposited in drops as with gap filler 104.

If desired, support structures in the location of gap filler 104 may be formed using support structures such as support structures 122 of FIGS. 8 and 9 (e.g., by extending some or all of layers 56, and 54 around the edges of ledge 106 to cover gap filler regions 104 of FIG. 6 without overlapping integrated circuits 100 and flexible printed circuit 102).

The foregoing is merely illustrative and various modifications can be made by those skilled in the art without departing from the scope and spirit of the described embodiments. The foregoing embodiments may be implemented individually or in any combination.

What is claimed is:

1. A display, comprising:
a display cover layer;
backlight structures;
display layers interposed between the display cover layer and the backlight structures, wherein the display layers include a thin-film transistor layer having a thin-film transistor ledge with opposing first and second surfaces; and
support structures between the second surface of the thin-film transistor ledge and the backlight structures, wherein the support structures include a part of a polarizer layer.

2. The display defined in claim 1 further comprising:
gap filler between the first surface of the thin-film transistor ledge and the display cover layer.

3. The display defined in claim 2 wherein the display layers include a first and second polarizer layers, wherein the part of the polarizer layer is a part of the second polarizer layer, and wherein the thin-film transistor layer is between the first and second polarizer layers.

4. The display defined in claim 3 wherein the display layers further comprise a color filter layer between the first polarizer and the thin-film transistor layer.

5. The display defined in claim 4 further comprising a layer of liquid crystal material between the color filter layer and the thin-film transistor layer.

6. The display defined in claim 5 further comprising a first layer of adhesive that attaches the second polarizer layer to the thin-film transistor layer.

7. The display defined in claim 6 wherein a portion of the first layer of adhesive is interposed between the second surface of the thin-film transistor ledge and the part of the second polarizer layer.

8. The display defined in claim 7 further comprising a second layer of adhesive between the second polarizer layer and the backlight structures.

9. The display defined in claim 8 wherein a portion of the second layer of adhesive is between the thin-film transistor ledge and the backlight structures and is between the second polarizer layer and the backlight structures.

10. The display defined in claim 9 wherein the backlight structures include a light guide layer and light-emitting diodes that emit light into the light guide layer.

11. The display defined in claim 10 wherein the gap filler comprises drops of adhesive and wherein the display further comprises at least one integrated circuit attached to the first surface between the drops of adhesive.

12. The display defined in claim 11 wherein the display cover layer comprises a layer selected from the group consisting of: a glass layer, a sapphire layer, and a plastic layer.

13. A display, comprising:
an outer transparent layer;
a backlight unit;
display layers interposed between the outer transparent layer and the backlight unit, wherein the display layers include a thin-film transistor layer and a color filter layer, wherein the color filter layer overlaps all but a given edge portion of the thin-film transistor layer; and
a stiffener layer between the thin-film transistor edge portion and the backlight unit.

14. The display defined in claim 13 wherein the stiffener layer comprises a plastic layer.

15. The display defined in claim 13 wherein the stiffener layer comprises a metal layer.

16. The display defined in claim 13 further comprising:
gap filler between the edge portion of the thin-film transistor layer and the outer transparent layer.

17. The display defined in claim 16 wherein the display layers include first and second polarizer layers and a layer of liquid crystal material between the color filter layer and the thin-film transistor layer and wherein the second polarizer layer does not overlap the edge portion of the thin-film transistor layer.

18. The display defined in claim 17 further comprising a first layer of adhesive that attaches the second polarizer layer to the thin-film transistor layer and a second layer of adhesive between the second polarizer layer and the backlight unit.

19. The display defined in claim 18 wherein a portion of the first layer of adhesive is interposed between the stiffener layer and the edge portion of the thin-film transistor layer.

20. The display defined in claim 19 wherein a portion of the second layer of adhesive is interposed between the stiffener layer and the backlight unit.

21. A display, comprising:
a glass layer;
a backlight;
a first substrate and a second substrate that are interposed between the glass layer and the backlight, wherein the first substrate overlaps a first portion of the second substrate and does not overlap a ledge portion of the second substrate;
first gap filler between the ledge portion and the glass layer; and
second gap filler between the ledge portion and the backlight.

22. The display defined in claim 21 wherein the first substrate comprises a color filter layer and wherein the second substrate comprises a thin-film transistor layer.

23. The display defined in claim 22 further comprising first and second polarizers, wherein the first polarizer overlaps the first substrate and does not overlap the ledge portion of the second substrate.

24. The display defined in claim 23 wherein the second polarizer overlaps the first substrate and does not overlap the ledge portion of the second substrate.

25. The display defined in claim 24 further comprising a flexible printed circuit that is attached to the second substrate between first and second respective portions of the first gap filler.

26. The display defined in claim 25 wherein the first and second gap filler comprise cured liquid adhesive.
